(19) United States
(12) Patent Application Publication
(10) Pub. No.: US 2023/0394896 A1
(43) Pub. Date: Dec. 7, 2023

(54) METHOD AND A SYSTEM FOR TESTING A DRIVER ASSISTANCE SYSTEM FOR A VEHICLE

(71) Applicant: AVL LIST GMBH, Graz (AT)

(72) Inventors: Mihai NICA, Graz (AT); Hermann FELBINGER, Weinitzen (AT); Jianbo TAO, Pudong Shanghai (CN); Florian KLÜCK, Graz (AT); Martin ZIMMERMANN, Graz (AT); Lorenz KLAMPFL, Graz (AT)

(21) Appl. No.: 18/248,716

(22) PCT Filed: Oct. 11, 2021
(86) PCT No.: PCT/AT2021/060370

§ 371 Date: Apr. 12, 2023

(30) Foreign Application Priority Data
Oct. 12, 2020 (AT) A 50877/2020

(51) Int. Cl. G07C 5/08

(52) U.S. Cl. CPC G07C 5/0808

(57) ABSTRACT

The invention relates to a computer-implemented method for testing a driver assistance system for a vehicle, comprising simulating a scenario in which the vehicle is situated; operating the driver assistance system in an environment of the vehicle on the basis of the simulated scenario; observing a driving behavior of the driver assistance system in the environment of the vehicle; determining a driving situation resulting from the driving behavior of the driver assistance system in the environment of the vehicle; establishing a quality of the simulated scenario as a function of a criticality of the resulting driving situation; checking at least one termination condition; and changing the simulated scenario on the basis of the established quality until the at least one termination condition with respect to the quality is met. The invention also relates to a corresponding system.

The invention relates to a computer-implemented method and a system for testing a driver assistance system for a vehicle, wherein a scenario in which the vehicle is situated is simulated and the driver assistance system is operated in an environment of the vehicle on the basis of the simulated scenario, and wherein driving behavior of the driver assistance system is observed in the environment of the vehicle.

The proliferation of driver assistance systems (Advanced Driver Assistance Systems—ADAS), which in a further development enables autonomous driving (Autonomous Driving—AD), keeps increasing in both the passenger car as well as the commercial vehicle sectors. Driver assistance systems make an important contribution to increasing active traffic safety and serve in enhancing driving comfort.

In addition to systems which in particular serve driving safety such as ABS (anti-lock braking system) and ESP (electronic stability program), a plurality of driver assistance systems are touted in the passenger and commercial vehicle sectors.

Driver assistance systems which are already being used to increase active road safety are park assist and adaptive automatic vehicle interval control, also known as Adaptive Cruise Control (ACC), which adaptively adjusts a desired speed selected by a driver to the distance from a vehicle driving ahead. A further example of such driver assistance systems are ACC stop-and-go systems which, in addition to ACC, effect the automatic further travel of the vehicle in a traffic jam or stationary traffic, lane departure warning or lane assist systems which automatically keep the vehicle in the vehicle lane, and pre-crash systems which for example ready or initiate braking in the event of a possible collision in order to draw the kinetic energy out of the vehicle as well as potentially initiate further measures should a collision be unavoidable.

These driver assistance systems increase safety in traffic by means of warning the driver of critical situations through to initiating autonomous intervention to prevent accidents or mitigate the consequences of an accident, for example by activating an emergency braking function. Additionally, functions like automatic parking, automatic lane-keeping and automatic proximity control increase driving comfort.

A driver assistance system's gains in safety and comfort are only perceived positively by the vehicle's occupants when the aid provided by the driver assistance system is safe, reliable and—to the extent possible—convenient.

Moreover, every driver assistance system, depending on its function, needs to handle given traffic scenarios with maximum safety for the vehicle itself and without endangering other vehicles or other road users respectively.

The respective degree of vehicle automation is divided into so-called automation levels 1 to 5 (see e.g. the SAE J3016 standard). The present invention relates in particular to vehicles having driver assistance systems of automation level 3 to 5, which is generally considered autonomous driving.

There are many diverse challenges in testing such systems. In particular, a balance needs to be found between the testing expenditure and the test coverage. The main task when testing ADAS/AD functions is thereby to demonstrate the guaranteed function of the driver assistance system in all conceivable situations, particularly including critical driving situations. Such critical driving situations involve a certain degree of danger since no reaction or a wrong reaction of the respective driver assistance system can lead to an accident.

The testing of driver assistance systems therefore requires allowing for a large number of driving situations which may arise in different scenarios. The range of possible scenarios thereby generally spans many dimensions (e.g. different road characteristics, behavior of other road users, weather conditions, etc.). From this virtually infinite and multidimensional range of parameters, it is particularly relevant in the testing of driver assistance systems to extract those parameter constellations for critical scenarios which can lead to unusual or dangerous driving situations.

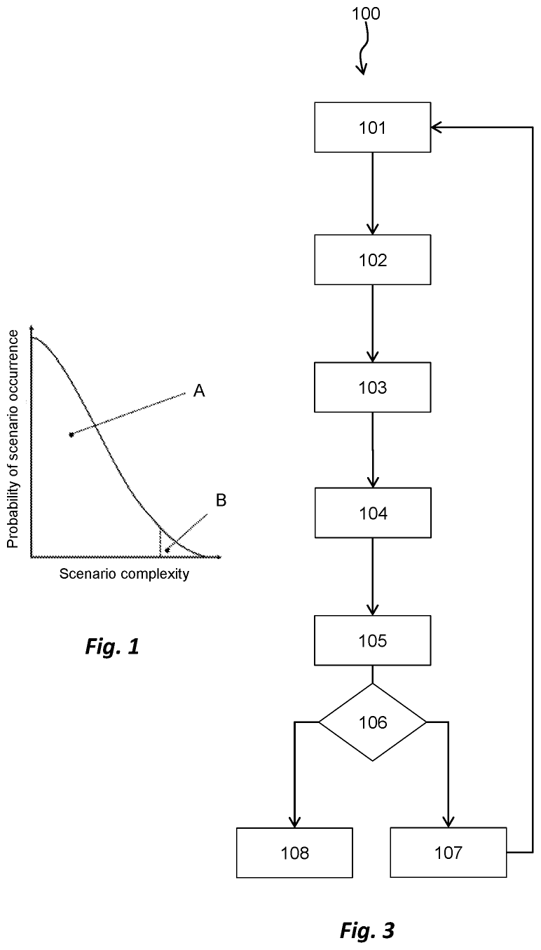

As depicted in FIG. 1, such critical scenarios have a much lower probability of occurrence than usual scenarios.

In order to validate a corresponding driver assistance system, scientific publications consider that operating a vehicle in autonomous driving operation is only statistically safer than a human-controlled vehicle when the respective driver assistance system has completed 275 million miles of accident-free driving. Real test drives cannot actually realize this, particularly considering that the development cycles and quality standards demanded in the automotive industry already set a very tight time frame. For the aforementioned reason, it would also be unlikely that a sufficient number of critical scenarios, or driving situations resulting from these scenarios respectively, would be included.

Using real test drive data from a real fleet of test vehicles to validate and verify driver assistance systems and to extract scenarios from the recorded data is known from the prior art. Furthermore, using full factorial designs for validation and verification is also known.

One task of the invention is that of being able to test driver assistance systems, in particular driver assistance systems for autonomous driving, in critical scenarios. Particularly a task of the invention is identifying critical scenarios for driver assistance systems. This task is solved by the teaching of the independent claims. Advantageous embodiments are found in the dependent claims.

A first aspect of the invention relates to a computer-implemented method for testing a driver assistance system for a vehicle, comprising the following work steps:
simulating a scenario in which the vehicle is situated;
operating the driver assistance system in an environment of the vehicle on the basis of the simulated scenario;
observing a driving behavior of the driver assistance system in the environment of the vehicle;
determining a driving situation resulting from the driving behavior of the driver assistance system in the environment of the vehicle;
establishing a quality of the simulated scenario as a function of the criticality of the resulting driving situation;
checking at least one termination condition; and
changing the simulated scenario on the basis of the established quality until the at least one termination condition with respect to the quality is met.

A second aspect of the invention relates to a system for testing a driver assistance system for a vehicle, comprising:
means for simulating a scenario in which the vehicle is situated;
means for operating the driver assistance system in an environment of the vehicle on the basis of the simulated scenario;
means for observing a driving behavior of the driver assistance system in the environment of the vehicle;
means for determining a driving situation resulting from the driving behavior of the driver assistance system in the environment of the vehicle;
means for establishing a quality of the simulated scenario as a function of the criticality of the resulting driving situation;
means for checking at least one termination condition; and
means for changing the simulated scenario on the basis of the established quality until a termination condition with respect to quality is met.

A third aspect of the invention relates to a system for testing a driver assistance system for a vehicle which comprises an agent, wherein the agent is configured to generate a scenario and provoke a driver assistance system error by changing the scenario, and wherein a strategy for changing the scenario is continuously improved by means of reinforcement learning methodology via agent interaction with the driver assistance system during operation until a termination condition is met.

An environment of the vehicle within the meaning of the invention is preferably formed at least by the objects relevant to the vehicle guidance provided by the driver assistance system. In particular, an environment of the vehicle includes a setting and dynamic elements. The setting preferably encompasses all stationary elements.

A scenario within the meaning of the invention is preferably formed from a chronological sequence of, in particular static, scenes. The scenes thereby indicate for example the spatial arrangement of the at least one other object relative to the ego object, e.g. the constellation of road users. A scenario can in particular incorporate a driving situation in which a driver assistance system at least partially controls the vehicle, which is called the ego vehicle and is equipped with the driver assistance system, for example autonomously executes at least one vehicle function of the ego vehicle.

A driving situation within the meaning of the invention preferably specifies the circumstances to be taken into account for the selection of suitable driver assistance system behavior patterns at a specific point in time. A driving situation is therefore preferably subjective in that it represents the point of view of the ego vehicle. It preferably further encompasses relevant conditions, contingencies and factors influencing actions. A driving situation is further preferably derived from the scene through an information selection process based on transients, e.g. mission-specific as well as permanent objectives and values.

Driving behavior within the meaning of the invention is preferably a behavior of the driver assistance system through action and reaction in an environment of the vehicle.

A quality within the meaning of the invention preferably characterizes the simulated scenario. A quality is preferably understood as a quality or condition of the simulated scenario relative to its suitability for testing the driver assistance system. In this context, a more critical scenario preferably has a higher quality. Preferably, the criticality of a driving situation resulting from the respective scenario for the tested driver assistance system is a measure of the scenario's quality.

Reinforcement learning is a method of machine learning in which an agent independently learns action within an environment. This thereby occurs by the agent trying different actions in an environment and receiving either a reward or a punishment through feedback from the environment. After a learning phase, the agent is capable of executing an action in the environment so as to receive the greatest possible reward for doing so.

An agent within the meaning of the invention preferably indicates a computer program or a module of a data processing system which is capable of a certain independent and inherently dynamic, in particular autonomous, behavior. That means that, depending on different conditions, in particular different statuses, a predetermined processing operation proceeds without any further start signal being given by external means or any external control intervention ensuing during the process.

The invention is based on the idea of iteratively improving simulated scenarios so as to be as suitable as possible for testing a driver assistance system. In other words, the simulated scenarios are improved in such a way as to be as suitable as possible in revealing or eliciting a possible error in the driver assistance system. Simulated scenarios are thereby specifically optimized for a specific driver assistance system or a function of a driver assistance system.

Preferably, provision can be made for the presence of a termination condition which, when met, effects the termination of the iterative process. Should such a termination condition not be met, a further termination condition such as, for example, a maximum testing period or even a maximum number of test kilometers completed by the vehicle in the simulated scenarios can be provided. The quality of the simulated scenario; i.e. that variable which valuates the simulated scenarios, preferably depends on a defined criterion in respect of a respective driving situation arising in each step of iteration.

Particularly the criticality of the driving situation can thereby be used as a criterion for the measure of quality. Further preferably, this measure of the quality is a calculated length of time until a point of collision, an accident probability and/or an inadequate driving behavior of the driver assistance system. Such inadequate driving behavior can for example be a violation of a traffic rule and/or a maneuver with an excessive risk of damage, in particular bodily injury.

The invention therefore takes an approach of a game with two “players,” wherein the method or the system for testing the driver assistance system attempts to iteratively generate scenarios of increasing complexity until a predefined criterion is violated, in particular a (safety) critical metric in terms of the driver assistance system functionality. In this case, the method or system for testing has “won.” In contrast, the tested driver assistance system “wins” if such a violation; i.e. meeting a termination condition, is not elicited.

The invention enables significantly reducing the number of road kilometers for testing a driver assistance system since the invention intuitively finds those scenarios which are particularly critical for the respective driver assistance system. The majority of scenarios can normally be easily handled by the respective driver assistance system. Yet neither can any weak points in the driver assistance system then be revealed.

During the testing process, a so-called agent, which can preferably be designed as a software module or sub-algorithm in the testing method, learns from the behavior of the tested driver assistance system and continuously improves the quality of the simulated scenario in order to elicit malfunction of the tested driver assistance system.

The testing method is thereby repeated iteratively until a change in the simulated scenario leads to a behavior of the driver assistance system that violates a predefined target value serving as a termination condition. Such a termination condition can be, for example, a length of time of less than 0.25 seconds until a collision time point or even a specific time budget, e.g. maximum 600 hours simulation time.

Given a sufficiently long enough time budget, the invention is able to achieve high probability of proper ADAS or AD system functioning. The informative value of the tests performed using the inventive teaching thereby depends on the algorithm used to change the simulated scenarios. Ideally, such an algorithm has a human-like intuition that can push a respective driver assistance system to its limits.

In one advantageous embodiment of the method for testing a driver assistance system, a vehicle speed, in particular an initial speed, and/or a vehicle trajectory is specified when simulating the scenario. Doing so enables empirical values to be factored into a test. An agent can thus already be put on the right path in developing a critical scenario.

In a further advantageous embodiment of the method for testing a driver assistance system, values of a scenario's parameters are changed when the simulated scenario is changed. In this case, the respective given scenario is adapted iteratively and thereby improved for testing the respective driver assistance system. This procedure is particularly advantageous when a specific scenario for testing a specific driver assistance system is to be “optimized.”

In a further advantageous embodiment of the method for testing a driver assistance system, depending on the type of driver assistance system to be tested, the parameters of the scenario are selected from the following group:
vehicle speed, in particular an initial speed; vehicle trajectory; lighting conditions; weather; road surface; number and position of static and/or dynamic objects; speed and direction of movement of dynamic objects; condition of signaling systems, in particular traffic light systems; traffic signs; vertical elevation, width and/or navigability of lanes, lane course, number of lanes.

In a further advantageous embodiment of the method for testing a driver assistance system, when the simulated scenario is changed, a new scenario is produced which preferably consists of successively combined scenarios. A new scenario is preferably characterized by the need to master new driving tasks. For example, the scenario of approaching an intersection is fundamentally different from the scenario of driving on the highway.

Replacing simulated scenarios with new scenarios offers the advantage of being able to cover many different driving situations during a test drive and being able to test many functions of the driver assistance system in a completely different environment. This increases the informative value of the testing method to a very significant extent. When creating a new scenario, completely new parameters in particular can also be provided for changing parameter values.

In a further advantageous embodiment of the method for testing a driver assistance system, a notional reward is credited when establishing the quality and the changing ensues on the basis of a function designed to maximize the reward. Preferably, the respective algorithm used in the invention, in particular an agent applying this algorithm, learns which changes to the existing simulated scenario or which changes to a new scenario are expedient for achieving the desired effect; i.e. which changes lead to critical scenarios and potentially provoke a malfunction of the driver assistance system or an accident.

In a further advantageous embodiment of the method for testing a driver assistance system, the quality is higher the more dangerous the respective driving situation is, particularly the shorter a calculated length of time is until a collision time point.

In a further advantageous embodiment, the simulated scenario is changed using evolutionary algorithms. Evolutionary algorithms are also referred to as genetic algorithms.

When changing such algorithms, different algorithms are crossed and mutated. The algorithms which result are used to establish candidates for the next step of iteration.

This selection can be made so as to select those candidates which have the highest probability of eliciting critical scenarios. Genetic evolutionary algorithms thereby offer a high degree of flexibility in optimizing existing scenarios in respect of predefined criteria.

In a further advantageous embodiment of the method for testing a driver assistance system, a utility function specifying which value a specific scenario has is approximated on the basis of the established quality. The algorithm or the agent sees this value of the simulated scenario as a type of reward and is preferably configured in a way as to thereby maximize the value and reward.

In a further advantageous embodiment of the method for testing a driver assistance system, the driver assistance system is simulated. A simulation of the driver assistance system is particularly advantageous since in this case no test bed is required to test the real components of a real driver assistance system. In particular, the inventive method can in this case be executed faster than real-time. The speed of the simulation is thereby only limited by the computing power allocated.

In a further advantageous embodiment of the method for testing a driver assistance system, a strategy for changing the scenario using a reinforcement learning methodology based on the established quality is continuously improved during the test operation until the termination condition is met. When employing reinforcement learning, an algorithm, or the agent respectively, independently learns a strategy for maximizing a received reward. Both positive as well as negative rewards can thereby be given for actions taken. The use of reinforcement learning allows a particularly effective optimization of the simulated scenarios.

In a further advantageous embodiment of the method for testing a driver assistance system, historical data from earlier test operations of a driver assistance system, in particular the driver assistance system to be tested, are taken into account when the scenario is initially simulated. The use of historical data can be utilized to pre-train the algorithm or the agent. This can thereby reduce the length of time it takes to find critical scenarios. Furthermore, algorithms or agents which were trained on another, in particular similar, ADAS or AD system can also be used. In particular, so-called regression tests can thus be performed in order to ensure that changes in previously tested parts of the driver assistance system's software do not induce any new errors.

In a further advantageous embodiment of the method for testing a driver assistance system, data relating to the environment of the vehicle is fed into the driver assistance system and/or the driver assistance system, in particular the sensors, are stimulated on the basis of the vehicle's environment during operation of the driver assistance system. In this case, the inventive method can be used to test a physically present driver assistance system. Preferably, the vehicle is simulated in the process. In principle, however, it is also conceivable for the entire vehicle including the driver assistance system to be tested on a test bed in such a manner. This embodiment offers the advantage of being able to test the driver assistance system with all of its components under the most realistic conditions possible.

In one advantageous embodiment of the system for testing a driver assistance system, the agent is configured to observe a driving situation resulting from the driver assistance system's driving behavior in an environment of the vehicle based on the simulated scenario and to establish a quality of the scenario as a function of the resulting driving situation's criticality.

In a further advantageous embodiment of the system for testing a driver assistance system, the agent is pre-trained on the basis of historical data. This data is taken into account by the agent when initially simulating the scenario.

The features and advantages previously described in relation to the first aspect of the invention also apply accordingly to the second and third aspect of the invention and vice versa.

Further features and advantages derive from the following description referencing the figures. Shown therein at least partly schematically:

FIG. 1 a diagram of the probability of occurrence of scenarios as a function of their complexity;

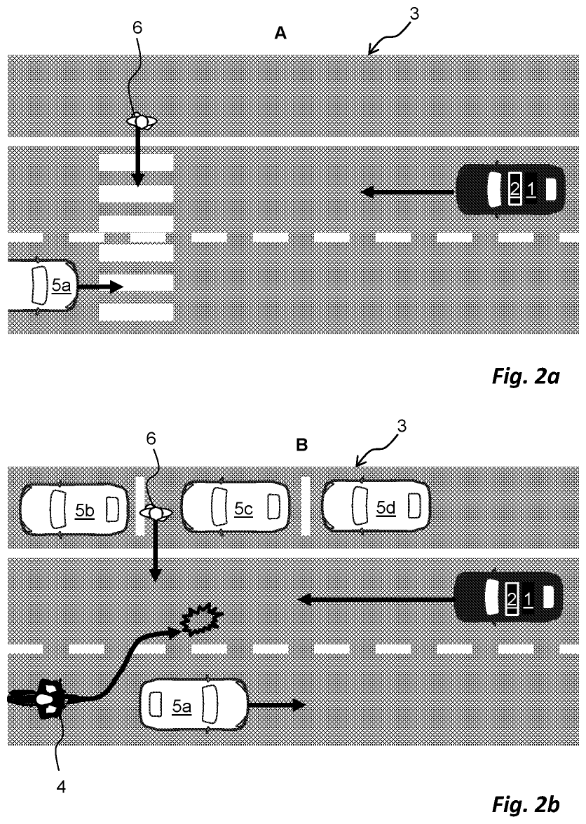

FIG. 2a an example of a scenario;

FIG. 2b an example of a scenario with higher complexity than that from FIG. 2a;

FIG. 3 an exemplary embodiment of a method for testing a driver assistance system; and

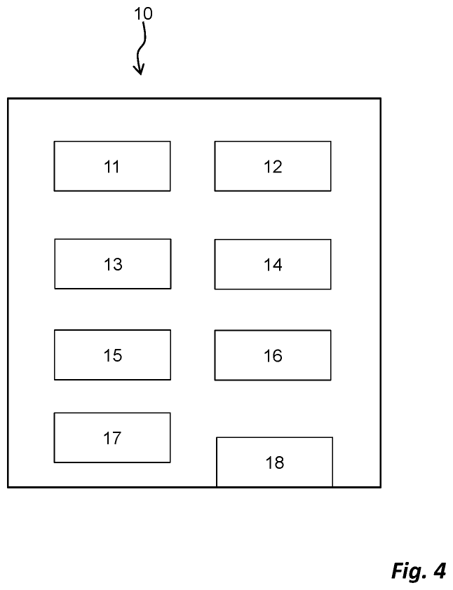

FIG. 4 an exemplary embodiment of a system for testing a driver assistance system.

FIG. 1 shows a diagram of the probability of occurrence of scenarios as a function of their complexity. The probability of occurrence is that probability with which scenarios occur in real road traffic.

Noticeable from FIG. 1 is that the majority of scenarios are of relatively low complexity, which also corresponds to the general life experience of a motorist. The range of these scenarios is labeled “A” in FIG. 1. In contrast, scenarios of high complexity occur relatively rarely, their range labeled “B” in FIG. 1. However, it is precisely those “B” scenarios of great complexity which are highly relevant to testing the functionality of driver assistance systems.

Therefore, obtaining a sufficient number and diversity of different scenarios of high “B” complexity when testing a driver assistance system requires running through a very high number of scenarios based on the distribution curve as shown.

FIG. 2a shows a first scenario 3 in which a pedestrian 6 crosses a crosswalk and a vehicle 1 controlled by a driver assistance system 2 as well as another vehicle 5a in the opposite lane approach the crosswalk. The driver assistance system 2 thereby controls both the longitudinal as well as the lateral movement of vehicle 1.

In the first scenario 3 shown in FIG. 2, both the pedestrian 6 as well as the course of the road, the crosswalk and the other oncoming vehicle 5a are clearly visible to the driver assistance system 2 via sensors. In the depicted example, the driver assistance system 2 recognizes that it needs to reduce the vehicle speed in order to be able to let the pedestrian 6 pass through the crosswalk. The movement of the other vehicle 5a is thereby unlikely to play any role. FIG. 2a therefore relates to a scenario 3 of comparatively low complexity.

In the second scenario 3 depicted in FIG. 2b, there is no crosswalk. Moreover, other vehicles 5b, 5c, 5d are parked alongside the lane of vehicle 1 controlled by the driver assistance system 2 through which the sensors of the driver assistance system 2 cannot detect the pedestrian 6, or can only do so with difficulty.

In addition to the pedestrian 6 and the parked vehicles 5b, 5c, 5d, there is a further vehicle 5a in the environment of vehicle 1 controlled by the driver assistance system 2 which is approaching vehicle 1 controlled by the driver assistance system 2, as in FIG. 2a.

There is a motorcyclist 4 riding behind said further vehicle 5a. There is no indication in FIG. 2b as to whether the motorcyclist can be detected in the environment of the vehicle 1 controlled by the driver assistance system 2. In scenario 3 as depicted, the motorcyclist 4 will attempt to pass the other vehicle 5a in the other lane. The pedestrian 6 will try to cross the street at the same time in the depicted scenario. In doing so, he takes no notice of the vehicle 1 controlled by the driver assistance system 2.

Depending on how the driver assistance system 2 reacts or acts in scenario 3; i.e. which driving behavior the driver assistance system 2 exhibits in the environment of the vehicle 1, there will be a resulting driving situation of dangerous or less dangerous. Should, for example, vehicle 2 continue driving at undiminished speed in the depicted scenario 3, as indicated in FIG. 2b by the arrows, a collision will likely occur between the vehicle 1 controlled by the driver assistance system 2 and the motorcycle 4. Such a driving situation would correspond to a very high criticality.

Due to the large volume of information which the driver assistance system 2 of the vehicle 1 needs to process in the scenario 3 shown in FIG. 2b and the potential problems that can arise from the constellation of road users 5a, 5b, 5c, 5d visible to the driver assistance system 2 in the environment, the second scenario 3 pursuant to FIG. 2b has a comparatively high complexity, particularly in comparison to the first scenario depicted in FIG. 2a.

FIG. 3 shows an exemplary embodiment of a method 100 for testing a driver assistance system for a vehicle 1.

In a first work step 101, a scenario 3 in which the vehicle 1 is located is simulated. Preferably, the environment of the vehicle 1 is on the one hand simulated with all the dynamic elements in FIG. 2b, for example the pedestrian 6, the other vehicle 5a and the motorcycle 4, as well as with the stationary elements in FIG. 2b of the other vehicles 5b, 5c, and the street.

A driver assistance system 2 can be simulated on the basis of said simulation, potentially together with the vehicle 1 it controls, preferably on a test bed 12. The sensors of the driver assistance system 2 are in this case preferably stimulated in such a way as to replicate the simulated scenario 3, or the environment of the vehicle 1 resulting from the simulated scenario 3 respectively. Suitable stimulators as known from the prior art are in particular used to that end.

Further preferably, the driver assistance system 2 or only the software of the driver assistance system 2 can be integrated into the simulation of the scenario 3 in the form of a hardware-in-the-loop test.

Lastly, it is also possible for the driver assistance system 2 or only just the software of the driver assistance system 2 to be simulated.

Further preferably, a speed, in particular an initial speed of the vehicle 1, and/or a trajectory of the vehicle 1 is specified when simulating the scenario. Moreover, historical data from earlier test operations of either the tested driver assistance system 2 or other driver assistance systems can preferably be taken into account when simulating the scenario. This historical data is particularly useful when determining an initial simulated test scenario. Furthermore, such historical data can preferably be used to train a so-called agent which tests the driver assistance system or an agent which has already been used to test a driver assistance system, in particular another driver assistance system, can be used.

In a second work step 102, the driver assistance system 2 is operated in the environment of the vehicle on the basis of the simulated scenario 3. If the driver assistance system 2 is also merely simulated, the operation of the driver assistance system 2 in the environment of the vehicle 1 controlled by the driver assistance system 2 is also merely simulated.

In a third work step 103, the driving behavior of the driver assistance system 2 in the environment of the vehicle 1 controlled by the driver assistance system 2 is observed.

On the basis of the data established by the observation, a driving situation arising at any point in time as a result of the driving behavior of the driver assistance system 2 in the environment of the vehicle 1 can be determined. This is preferably realized in a fourth work step 100.

Based on the resultant driving situation, the driver assistance system 2 has to make new decisions as to how it behaves and controls the vehicle 1 which it controls.

The respective resultant driving situation in the simulated scenario 3 can be objectively examined with regard to criticality. In particular, an accident probability and a length of time until a collision time point can be calculated for each time step of the simulation on the basis of the information available from scenario 3.

For example, in scenario 3 of FIG. 2b, if the vehicle 1 controlled by the driver assistance system 2 continues driving straight ahead at undiminished speed, the length of time until the point of collision could be calculated.

The accident probability can be influenced by, for example, assessing the adequacy of the driving behavior of the driver assistance system 2. An accident probability in scenario 3 of FIG. 2a or FIG. 2b would for example be increased when the vehicle 1 controlled by the driver assistance system 2 drives at highly excessive speed.

In a fifth work step 105, the quality of the simulated scenario 3 is established as a function of a predefined criterion in relation to the resulting driving situation. The quality thereby in particular ensues from the complexity of the simulated scenario, wherein a higher complexity of the simulated scenario 3 denotes a higher quality. Preferably, the quality thereby indicates how the driving situation resulting from the driving behavior of the driver assistance system 2 is to be assessed in relation to a predefined criterion. Such a criterion can for example be the criticality of the resulting driving situation, which is characterized by the accident probability and/or the length of time before a possible collision. Furthermore, the criticality can also be characterized by a probability of inadequate driving behavior of the driver assistance system 2.

A check is now made in a sixth work step 106 as to whether a termination condition has been met. Such a termination condition can on the one hand be defined by a predefined criterion in relation to the resultant driving situation, for example a limit value for a maximum length of time until a collision time point or even a maximum accident probability. A maximum testing period can also be additionally specified as a further termination condition.

If the termination condition is met, the simulated scenario, or the parameter values of the simulated scenario and/or the quality of the simulated scenario respectively, are exported in an eighth work step 108, in particular in the form of a test report.

If the termination condition is not met, the simulated scenario 3 is then changed on the basis of the established quality in a seventh work step 107. At this point the testing method starts over again from the beginning with the first work step 101. The work steps are performed iteratively preferably until at least one of the termination conditions is met.

There are basically two different approaches to changing the simulated scenario in the seventh work step 107. Firstly, only values of the simulated scenario's parameters can be changed. In this case, the changed simulated scenario always builds on the simulated scenario used in the previous iteration step. This approach is then used particularly when the simulated scenario 3 is changed by means of so-called evolutionary algorithms.

Alternatively, a new scenario is produced when the simulated scenario is changed. In particular, parameters can be replaced, parameters can be omitted and/or new parameters can be added in such a new scenario.

This approach is used particularly when a reinforcement learning methodology based on the established quality is used for the scenario changing strategy. With reinforcement learning, this strategy is continuously improved throughout the test operation until the termination condition is met. Preferably, a utility function specifying which quality value a specific simulated scenario has is approximated in this case on the basis of the established quality.

As already mentioned, the algorithm that changes the scenarios can preferably be designed as a so-called agent. In this case, the testing method resembles a two-player game, wherein the agent plays against the driver assistance system 2 in order to provoke a driver assistance system 2 error.

Preferably, the quality is characterized by a notional reward and the change ensues on the basis of a cost function or an optimization of the cost function. Preferably, the cost function is designed to maximize the notional reward. Preferably, the higher the quality, the more dangerous the respective resulting driving situation is, particularly the shorter the calculated length of time until a collision time point.

A workflow which encompasses a method for testing a driver assistance system can additionally comprise the following work steps: In a first further work step, the tested driver assistance system together with an applicable vehicle dynamics model, e.g. VSM®, is integrated into a suitable modeling and integration platform, e.g. MobiConnect®. A 3D simulation environment is also preferably provided on this integration platform.

In a second further work step, a scenario template is generated which generically specifies the road properties, e.g. via OpenDRIVE®, road users and vehicle maneuvers, e.g. via OpenSCENARIO®. Optionally, virtual scenarios based on data from a real driving operation can be used in the generation. For example, GPS data, sensor data, object lists, etc. are suitable to that end.

In a third further work step, those parameters via which a scenario changing algorithm can change the scenarios are identified and selected. Value ranges within which these parameters can range are then defined for the parameters. For example, it could be specified that the algorithm can continuously assign values between 5 and 35 m/s for the scenario parameter of “vehicle speed of the vehicle ahead.” Preferably, not only parameters relating to the environment of the vehicle 1 controlled by the driver assistance system 2 can be selected here but trajectories of the vehicle 1 can also be selected for changing by the algorithm. Trajectories can also be changed as parameters for other road users. Individual trajectories are thereby defined for each road user using waypoints and time steps The trajectories can then be changed by changing the position of the waypoints and the distance between the waypoints.

In a fourth further work step, specific criteria serving to control the iterative generation of scenarios are predefined. If the predefined criterion is the length of time until a point of collision, the algorithm will attempt to minimize this length of time and search the scenarios for parameter values resulting in an accident.

Suitable termination conditions are defined in a fifth further work step. A possible termination condition is, for example, a 0.25-second length of time until a collision time point or the reaching of a maximum number of iterations.

In a further sixth work step, an initial set of parameter values is generated. These are randomly generated, manually selected or selected on the basis of real test drives. Together with the already generated scenario template, concrete scenarios able to be executed in the 3D simulation can in this way be generated.

The method for testing a driver assistance system as described above can then be executed.

FIG. 4 shows an exemplary embodiment of a system for testing a driver assistance system.

This system 10 preferably comprises means 11 for simulating a scenario in which the vehicle 1 is situated, means 12 for operating the driver assistance system 2 in an environment of the vehicle 1 on the basis of the simulated scenario, means 13 for observing a driving behavior of the driver assistance system 2 in the environment of the vehicle 1, means 14 for determining a driving situation resulting from the driving behavior of the driver assistance system 2 in the environment of the vehicle, means 15 for establishing a quality of the simulated scenario 3 as a function of a predefined criterion in relation to the driving situation, in particular a criticality of the resulting driving situation, means for checking a termination condition 16, and means 17 for changing the simulated scenario 3 on the basis of the established quality until a termination condition is met.

Preferably, the aforementioned means are formed by a data processing system. However, the means 12 for operating the driver assistance system in an environment of the vehicle 1 can also be formed by a test bed, in particular a test bed for a driver assistance system or a vehicle. Either way, the means 13 for observing a driving behavior of the driver assistance system 2 can be in part formed by sensors here.

The means 17 for changing the simulated scenario can preferably be in the form of an agent.

Preferably, the system comprises an interface 18 which can preferably be designed as a user interface or as a data interface.

It is noted that the exemplary embodiments are only examples not intended to limit the scope of protection, application and configuration in any way. Rather, the foregoing description is to provide the person skilled in the art with a guideline for implementing at least one exemplary embodiment, whereby various modifications can be made, particularly as regards the function and arrangement of the described components, without departing from the scope of protection resulting from the claims and equivalent combinations of features.

### LIST OF REFERENCE NUMERALS

A, B range of scenarios
1 vehicle
2 driver assistance system
3 scenario
4 motorcycle
5b, 5c, 5d further vehicles
6 pedestrian
11 simulation means
12 means for operating a driver assistance system
13 means for observing a driving behavior
14 means for determining a driving situation
means for establishing a quality
16 means for changing a scenario
17 means for checking a termination condition
18 interface

What is claimed is:

1. A computer-implemented method for testing a driver assistance system for a vehicle, comprising the following work steps:
simulating a scenario in which the vehicle is situated;
operating the driver assistance system in an environment of the vehicle on the basis of the simulated scenario;
observing a driving behavior of the driver assistance system in the environment of the vehicle;
determining a driving situation resulting from the driving behavior of the driver assistance system in the environment of the vehicle;
establishing a quality of the simulated scenario as a function of a predefined criterion in relation to the resulting driving situation, in particular a criticality of the resulting driving situation;
checking at least one termination condition of the method; and
changing the simulated scenario on the basis of the established quality until the at least one termination condition is met,
wherein a new scenario is produced when the simulated scenario is changed in which parameters are replaced, parameters are omitted and/or new parameters are added.

2. The method according to claim 1, wherein a speed, in particular an initial speed, of the vehicle and/or a trajectory of the vehicle is specified when simulating the scenario.

3. The method according to claim 1, wherein only values of parameters of the simulated scenario are changed when changing the simulated scenario.

4. The method according to claim 1, wherein a new scenario, which consists of successively combined scenarios, is produced when changing the simulated scenario.

5. The method according to claim 1, wherein the quality is characterized by a notional reward when establishing the quality and the changing ensues on the basis of a cost function designed to maximize the notional reward.

6. The method according to claim 1, wherein the simulated scenario is changed using evolutionary algorithms.

7. The method according to claim 1, wherein a utility function specifying which quality value a specific simulated scenario has is approximated on the basis of the established quality.

8. The method according to claim 1, wherein the driver assistance system is simulated.

9. The method according to claim 1, wherein a strategy for changing the scenario is continuously improved during the test operation using a reinforcement learning methodology based on the established quality until the termination condition is met.

10. The method according to claim 1, wherein historical data from earlier test operations of a driver assistance system, in particular the driver assistance system to be tested, are taken into account when the scenario is initially simulated.

11. The method according to claim 1, wherein data relating to the environment of the vehicle is fed into the driver assistance system and/or the driver assistance system, in particular its sensors, are stimulated on the basis of the environment of the vehicle during operation of the driver assistance system.

12. A system for testing a driver assistance system for a vehicle, comprising:
means for simulating a scenario in which the vehicle is situated;
means for operating the driver assistance system in an environment of the vehicle on the basis of the simulated scenario;
means for observing a driving behavior of the driver assistance system in the environment of the vehicle;
means for determining a driving situation resulting from the driving behavior of the driver assistance system in the environment of the vehicle;
means for establishing a quality of the simulated scenario as a function of a predefined criterion in relation to the driving situation, in particular a criticality of the resulting driving situation;
means for checking at least one termination condition of the method; and
means for changing the simulated scenario on the basis of the established quality until the at least one termination condition is met,
wherein a new scenario is produced when the simulated scenario (3) is changed in which parameters are replaced, parameters are omitted and/or new parameters are added.

13. A system for testing a driver assistance system for a vehicle, in particular according to claim 14, comprising an agent, wherein the agent is configured to generate a scenario and provoke an error of the driver assistance system by changing the scenario, and wherein a strategy for changing the scenario is continuously improved, in particular by means of a reinforcement learning methodology, via interaction of the agent with the driver assistance system during operation until a termination condition is met.

14. The system according to claim 13, wherein the agent is configured to observe a driving situation resulting from a driving behavior of the driver assistance system in an environment of the vehicle on the basis of the simulated scenario and establish a quality of the scenario as a function of a criticality of the resulting driving situation.

15. The system according to claim 13, wherein the agent is pre-trained on the basis of historical data and this data is taken into account by the agent when initially simulating the scenario.
